(19) United States
(12) Patent Application Publication
(10) Pub. No.: US 2014/0329347 A1
(43) Pub. Date: Nov. 6, 2014

(54) METHOD FOR MANUFACTURING LIGHT EMITTING DIODES

(71) Applicant: ADVANCED OPTOELECTRONIC TECHNOLOGY, INC., Hsinchu Hsien (TW)

(72) Inventors: CHING-HSUEH CHIU, Hukou (TW); YA-WEN LIN, Hukou (TW); PO-MIN TU, Hukou (TW); SHIH-CHENG HUANG, Hukou (TW)

(73) Assignee: ADVANCED OPTOELECTRONIC TECHNOLOGY, INC., Hsinchu Hsien (TW)

(21) Appl. No.: 14/221,241

(22) Filed: Mar. 20, 2014

(30) Foreign Application Priority Data
May 2, 2013 (CN) 2013101581623

(51) Int. Cl. H01L 33/10; H01L 33/00

(52) U.S. Cl. CPC H01L 33/10; H01L 33/0075
USPC 438/29

(57) ABSTRACT

An exemplary method for manufacturing a light emitting diode includes following steps: providing a substrate; growing an undoped GaN layer on the substrate, the undoped GaN layer comprising an upper surface away from the substrate and a lower surface contacting the substrate; etching the upper surface of the undoped GaN layer to form a plurality of cavities; growing an Distributed Bragg Reflector layer on the upper surface of the undoped GaN layer; and forming sequentially an N-type GaN layer, an active layer and a P-type GaN layer on the Distributed Bragg Reflector layer.

### BACKGROUND

1. Technical Field

This disclosure generally relates to light emitting diodes (LEDs), and particularly to a method for manufacturing a light emitting diode having a wave-shaped Distributed Bragg Reflector layer.

2. Description of Related Art

A typical light emitting diode includes a substrate, a buffer layer formed on the substrate, an N-type semiconductor layer formed on the buffer layer, an active layer formed on the N-type semiconductor layer, and a P-type semiconductor layer formed on the active layer. However, light emitting towards the substrate from the active layer tends to be absorbed by the buffer layer and the substrate, which decreases the light efficiency of the light emitting diode.

What is needed, therefore, is a method for manufacturing a light emitting diode which can overcome the forgoing drawback.

### BRIEF DESCRIPTION OF THE DRAWINGS

FIGS. 1-5 show steps of a method for manufacturing a light emitting diode according to an embodiment of the present disclosure.

### DETAILED DESCRIPTION

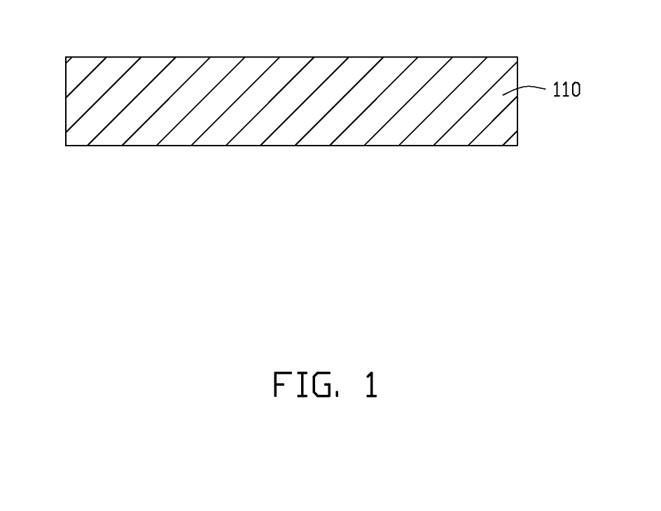

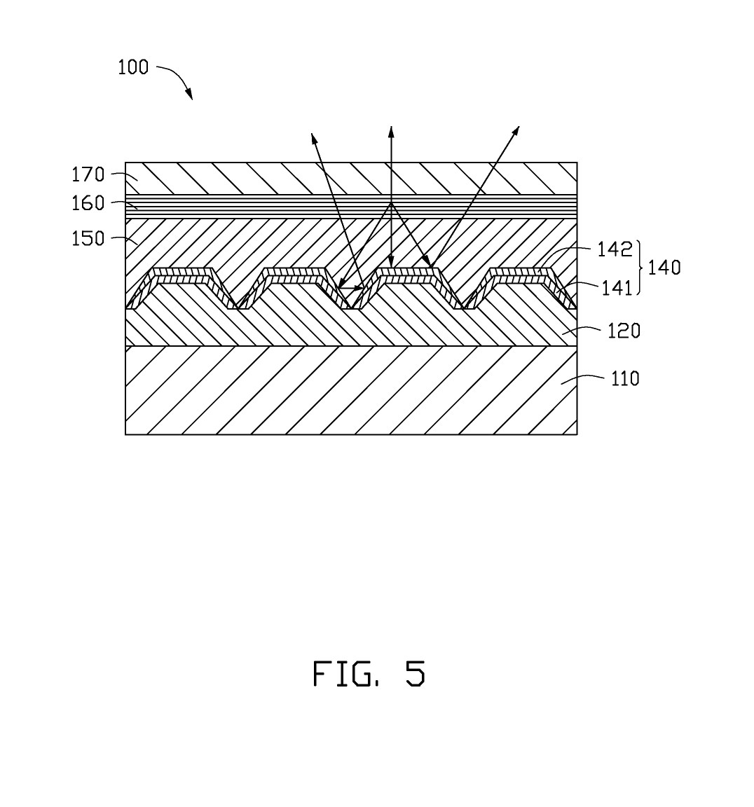

Referring to FIG. 1, the first step of a method for manufacturing a light emitting diode 100 (FIG. 5) in accordance with the present disclosure is related to providing a substrate 110. The substrate 110 includes a top surface and a bottom surface parallel and opposite to the top surface. The substrate 110 is made of sapphire,

Si, or Sic.

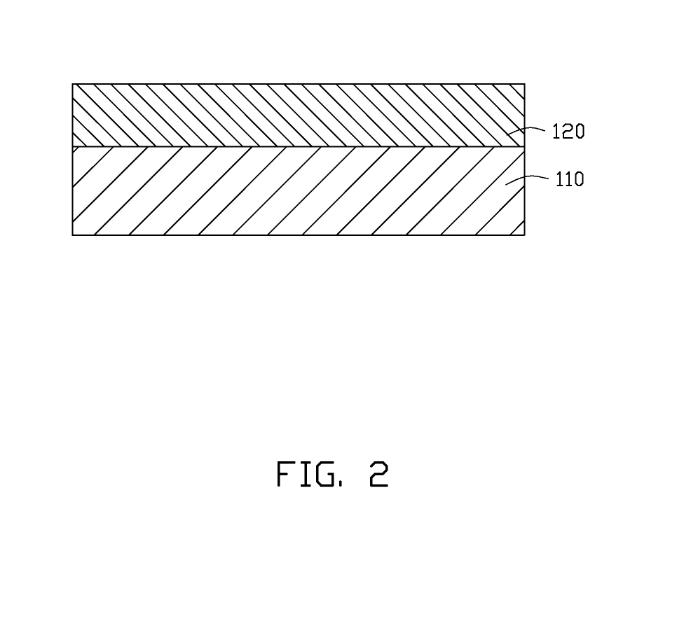

Referring to FIG. 2, the second step is related to growing an undoped GaN layer 120 on the substrate 110. The undoped GaN layer 120 is formed on the top surface of the substrate 110. The undoped GaN layer 120 includes an upper surface away from the substrate 110 and a lower surface contacting with the top surface of the substrate 110.

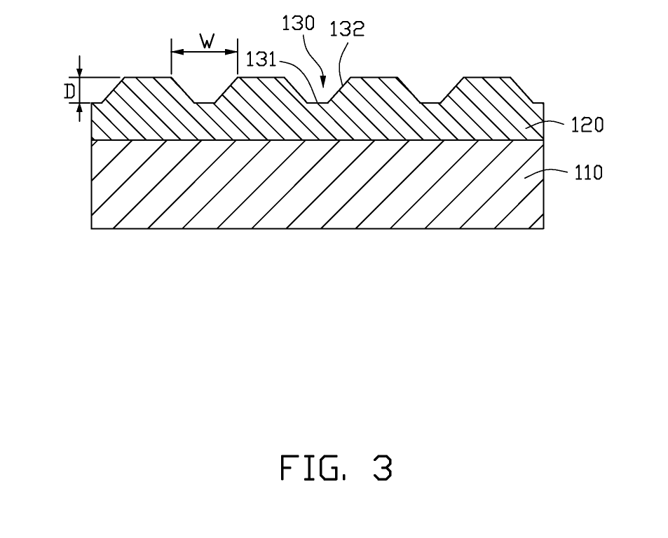

Referring to FIG. 3, the third step is related to etching the upper surface of the undoped GaN layer 120 to form a plurality of cavities 130. In this embodiment, the cavities 130 are defined by a dry etching process or a wet etching process.

Each cavity 130 is recessed downwardly along a direction from the upper surface to the lower surface of the undoped GaN layer 120. Each cavity 130 is defined by a bottom surface 131 and side surfaces 132 extending upwardly and slantways from opposite sides of the bottom surface 131. A size of an opening of the cavity 130 is gradually decreased along the direction from the upper surface of the undoped GaN layer 120 to the lower surface of the undoped GaN layer 120. A depth D of each cavity 130 is less than a thickness of the undoped GaN layer 120.

Preferably, a depth D of each cavity 130 ranges from 50 nm to 300 nm, and a width W of the opening of each cavity 120 at a top thereof is 3 um.

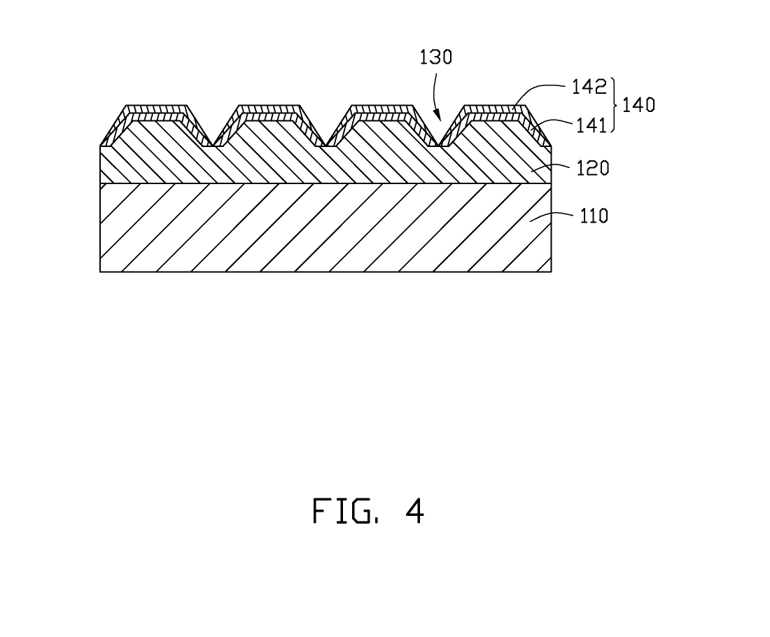

Referring to FIG. 4, the fourth step is related to growing a Distributed Bragg Reflector (DBR) layer 140 on the upper surface of the undoped GaN layer 120. Because the plurality of cavities 130 is defined in the upper surface of the undoped GaN layer 120, the Distributed Bragg Reflector layer 140 is wave-shaped. The Distributed Bragg Reflector layer conformably extends over the upper surface defining bottoms of the cavities 120 and the upper surface around the cavities 120. In this embodiment, the Distributed Bragg Reflector layer 140 includes an Al₁₋ₓGaₓN, (1>x≧0) layer 141 and a GaN layer 142 stacked on the Al₁₋ₓGaₓN, (1>x≧0) layer 141. The Al₁₋ₓGaₓN, (1>x≧0) layer 141 covers the entire upper surface of the undoped GaN layer 120, and the GaN layer 142 covers the Al₁₋ₓGaₓN, (1>x≧0) layer 141. Alternatively, more than one Distributed Bragg Reflector layer 140 may be provided to be stacked on the upper surface of the undoped GaN layer 120. The more the Distributed Bragg Reflector layer 140 is provided, the greater the light extraction efficiency of the light emitting diode 100 is.

Referring to FIG. 5, the fifth step is related to forming sequentially an N-type GaN layer 150, an active layer 160 and a P-type GaN layer 170 on the Distributed Bragg Reflector layer 140 to form the light emitting diode 100. The active layer 160 is a multi-quantum well layer.

According to the method for manufacturing the light emitting diode 100 of the embodiment of the present disclosure, light emitting away from the substrate 110 directly travels through the P-type GaN layer 170 to emit out of the light emitting diode 100. Light emitting towards the substrate 110 is reflected by the Distributed Bragg Reflector layer 140 to sequentially emit through the N-type GaN layer 150, the active layer 160 and the P-type GaN layer 170 to emit out of the light emitting diode 100. In addition, because the Distributed Bragg Reflector layer 140 is wave-shaped which is a three-dimensional structure, not only the light vertical to the substrate 110 emitted from the active layer 160 is effectively reflected by the Distributed Bragg Reflector layer 140, but also the light not vertical to the substrate 110 emitted from the active layer 160 is effectively reflected by a portion of the Distributed Bragg Reflector layer 140 located in the cavity 130 defined in the undoped GaN layer 120.

Furthermore, because the Distributed Bragg Reflector layer 140 is formed between the undoped GaN layer 120 and the N-type GaN layer 150, growth defects of the undoped GaN layer 120 is stopped by the Distributed Bragg Reflector layer 140 to enable the N-type GaN layer 150 to have an epitaxial growth with a better quality; accordingly, the active layer 160 and the P-type GaN layer 170 can also have a better quality. The formation of the cavities 130 in the un-doped GaN layer 120 can effectively release internal stress formed due to the formation of the un-doped GaN layer 120, whereby the possibility of formation of cracks in the Distributed Bragg Reflector layer 140 due to the internal stress can be lowered. Finally, since the Al₁₋ₓGaₓN, (1>x≧0) layer 141 and GaN layer 142 for constituting the Distributed Bragg Reflector layer 140 have different lattice constants, the lattice defect density of the Distributed Bragg

Reflector layer 140 can be lowered due to lattice dislocation, whereby a yielding rate of the light emitting diode 100 can be increased.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A method for manufacturing a light emitting diode, comprising:
providing a substrate;
growing an undoped GaN layer on the substrate, the undoped GaN layer comprising an upper surface away from the substrate and a lower surface contacting the substrate;
etching the upper surface of the undoped GaN layer to form a plurality of cavities;
growing an Distributed Bragg Reflector layer on the upper surface of the undoped GaN layer, the Distributed Bragg Reflector layer conformably extending over the upper surface defining bottoms of the cavities and the upper surface around the cavities; and
forming sequentially an N-type GaN layer, an active layer and a P-type GaN layer on the Distributed Bragg Reflector Layer.

2. The method for manufacturing a light emitting diode of claim 1, wherein the plurality of cavities are formed in the upper surface of the undoped GaN layer by a dry etching process or a wet etching process.

3. The method for manufacturing a light emitting diode of claim 1, wherein a depth of each cavity is less than a thickness of the undoped GaN layer.

4. The method for manufacturing a light emitting diode of claim 1, wherein a depth of each cavity ranges from 50 nm to 300 nm.

5. The method for manufacturing a light emitting diode of claim 4, wherein a width of each cavity at a top thereof is 3 um.

6. The method for manufacturing a light emitting diode of claim 1, wherein the Distributed Bragg Reflector layer comprises an Al₁₋ₓGaₓN, (1>x≧0) layer and a GaN layer stacked on the Al₁₋ₓGaₓN, (1>x≧0) layer.

7. The method for manufacturing a light emitting diode of claim 1, wherein the substrate is made of sapphire, Si, or SiC.

8. The method for manufacturing a light emitting diode of claim 1, wherein the active layer is a multi-quantum well layer.

9. The method for manufacturing a light emitting diode of claim 1, wherein the Distributed Bragg Reflector layer comprises a plurality of GaN layers and a plurality of Al₁₋ₓGaₓN, (1>x≧0) layers alternately stacked on the GaN layer.
